(19) United States
(12) Patent Application Publication
(10) Pub. No.: US 2008/0068229 A1
(43) Pub. Date: Mar. 20, 2008

(54) TOUCHPAD TESTING MACHINE

(75) Inventor: TSUNG-JEN CHUANG, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/845,788

(22) Filed: Aug. 28, 2007

(30) Foreign Application Priority Data
Sep. 15, 2006 (CN) 200610200879.X

(51) Int. Cl. H03M 11/00

(52) U.S. Cl. 341/34

(57) ABSTRACT

A touchpad testing machine for testing resistive touchpad includes a conductive rubber; a processing unit for generating a pressure control signal and a positioning control signal; a positioning controller for moving the conductive rubber to touch test points of the touchpad, according to the positioning control signal; a pressure controller for exerting a pressing force on a touchpad via the conductive rubber, according to the pressure control signal; and an analog-to-digital converter (ADC) for receiving sensing signals generated from the touchpad through the conductive rubber when receiving the pressing force, and for converting the sensing signals into digital values Another touchpad testing machine for testing capacitive touchpad is also provided in the invention.

### BACKGROUND OF THE INVENTION

1. Field of the Invention

The present invention is generally related to testing machines, and particularly to a testing machine used for testing touchpads under different test conditions.

2. Description of Related Art

A touchpad is an input device commonly employed as a pointing device in laptop computers. A touchpad is used to move a cursor by detecting directional motions of a user's finger. A touchpad is a substitute for a computer mouse. There are two major types of touchpads: resistive touchpad and capacitive touchpad. The resistive touchpad consists of two flexible membranes, one membrane being on top of the other membrane. When a finger or any other object applies a certain pressure on the top membrane, the top membrane touches or makes contact with the underlying or bottom membrane. A controller connected with the underlying or bottom membrane recognizes where the two membranes touch each other and sends information to the PC. The capacitive touchpad consists of a printed circuit board (PCB) covered with a front membrane and generates an electrical field above the front membrane of the PCB. When a finger touches any place on the front membrane, the electrical field is changed. A controller connected to the PCB detects this change in the electrical field, relates it to the position touched on the pad, and sends this position information to the PC.

The test of touchpads includes stability test, durability test, and accuracy test according to the structure of the touchpad mentioned above. However, nowadays, many tests for a touchpad are omitted, more particularly, there is a lack of professional testing machine to test touchpads. Therefore, a heretofore need exists in the industry to overcome the aforementioned deficiencies.

### SUMMARY OF THE INVENTION

A touchpad testing machine includes a conductive rubber; a processing unit for generating a pressure control signal and a positioning control signal; a positioning controller for moving the conductive rubber to touch test points of the touchpad, according to the positioning control signal; a pressure controller for exerting a pressing force on a touchpad via the conductive rubber, according to the pressure control signal; and an analog-to-digital converter (ADC) for receiving sensing signals generated from the touchpad through the conductive rubber when receiving the pressing force, and for converting the sensing signals into digital values.

A touchpad testing machine includes a conductive rubber; a processing unit for generating a static electricity producing signal and a positioning control signal; a static electricity producer for accumulating static electricity on a touchpad according to the static electricity producing signal; a positioning controller for driving the conductive rubber to touch test points of the touchpad, according to the positioning control signal; and an ADC for receiving sensing signals generated from the touchpad through the conductive rubber after receiving static electricity, and for converting the sensing signals into digital values.

Other features of the embodiments will be drawn from the following detailed description together with the attached drawings.

### BRIEF DESCRIPTION OF THE DRAWINGS

FIG. 1 is a block diagram of a touchpad testing machine in accordance with a first preferred embodiment of the present invention;

FIG. 2 is a block diagram of a touchpad testing machine in accordance with a second preferred embodiment of the present invention; and

FIG. 3 is a block diagram of a touchpad testing machine in accordance with a third preferred embodiment of the present invention.

### DETAILED DESCRIPTION OF THE INVENTION

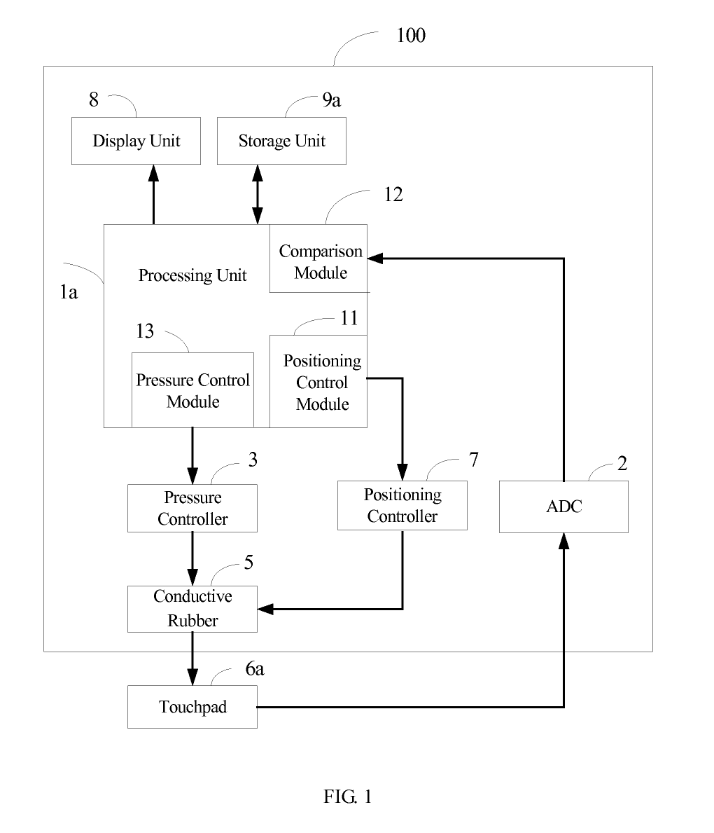

FIG. 1 is a block diagram of a touchpad testing machine in accordance with a first preferred embodiment of the present invention. The touchpad testing machine 100 is configured for testing a resistive touchpad 6a based on different profiles, such as, child, adult female, adult male, elderly, or the like. Each profile is assigned with a group of first test data. The first test data consist of procedural data and expected results. The procedural data include but not limited to, test points and test pressure. Each of the test points is identified by coordinates. The touchpad testing machine 100 includes a positioning controller 7, an analog-to-digital converter (ADC) 2, a pressure controller 3, a conductive rubber 5, a display unit 8, a storage unit 9a, and a processing unit 1a.

The pressing unit 1a includes a positioning control module 11, a comparison module 12, and a pressure control module 13. The positioning control module 11 is programmed for generating a positioning control signal and transmitting the positioning control signal to the positioning controller 7. The pressure control module 13 is programmed for generating a pressure control signal and transmitting the pressure control signal to the pressure controller 3.

The pressure controller 3 exerts a pressing force on the conductive rubber 5 according to the pressure control signal, as a consequence, the conductive rubber 5 contacts the resistive touchpad 6a. The positioning controller 7 drives the conductive rubber 5 to touch the test points of the resistive touchpad 6a according to the positioning control signal.

The storage unit 9a is configured for storing the first test data associated with the profiles. For exemplary purposes, a plurality of tables including the first test data are illustrated as follows. Each table corresponds to one profile and lists the first test data associated with the profile.

TABLE 1
Adult male Profile

| Test Point | Procedural Data/Test Pressure | Expected Result |
|---|---|---|
| A (x1, y1) | P1 | P1a |
| B (x2, y2) | P1 | P1b |
| C (x3, y3) | P1 | P1c |
| D (x4, y4) | P1 | P1d |
| . . . | P1 | . . . |

TABLE 2
Adult female Profile

| Test Point | Procedural Data/Test Pressure | Expected Result |
|---|---|---|
| A (x1, y1) | P2 | P2a |
| B (x2, y2) | P2 | P2b |
| C (x3, y3) | P2 | P2c |
| D (x4, y4) | P2 | P2d |
| . . . | P2 | . . . |

TABLE 3
Child Profile

| Test Point | Procedural Data/Test Pressure | Expected Result |
|---|---|---|
| A (x1, y1) | P3 | P3a |
| B (x2, y2) | P3 | P3b |
| C (x3, y3) | P3 | P3c |
| D (x4, y4) | P3 | P3d |
| . . . | P3 | . . . |

TABLE 4
Elderly Profile

| Test Point | Procedural Data/Test Pressure | Expected Result |
|---|---|---|
| A (x1, y1) | P4 | P4a |
| B (x2, y2) | P4 | P4b |
| C (x3, y3) | P4 | P4c |
| D (x4, y4) | P4 | P4d |
| . . . | P4 | . . . |

When testing the capacitive touchpad 6a with the touch pad testing machine 100 in the first preferred embodiment, the positioning control module 11 obtains the first test data (i.e., the test points) associated with a corresponding profile (e.g., table 1) from the storage unit 9a, and controls a movement of the conductive rubber 5 according to the coordinates of the test points so as to touch and test the test points with the conductive rubber 5. When the conductive rubber 5 reaches one of the test points (e.g., point A), the pressure control module 13 reads the test pressure (e.g., P1 as that shown in table 1) corresponding to the test point A. When the conductive rubber 5 applies the pressing force on the resistive touchpad 6a, the resistive touchpad 6a generates and sends an sensing signal to the ADC 2. The ADC 2 converts the sensing signals into digital values and sends the digital values to the comparison module 12. The comparison module 12 compares the digital values with the expected results (e.g. P1a as that shown in table 1) from the storage unit 9a, and transmits a comparison result to the displayed unit 8 of the touchpad testing machine 100. The touchpad testing machine 100 repeats this procedure to test other test points.

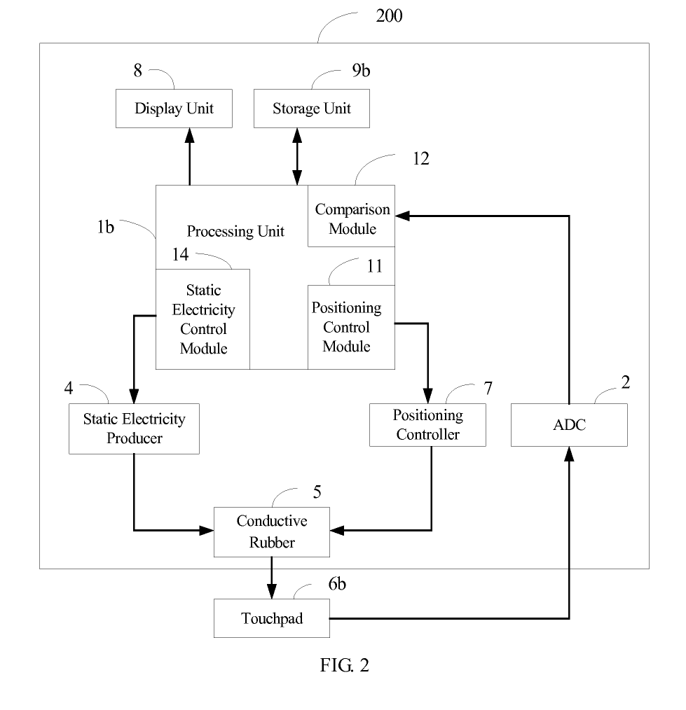

FIG. 2 is a block diagram of the touchpad testing machine 200 in accordance with a second preferred embodiment of the present invention. The touchpad testing machine 200 is configured for testing a capacitive touchpad 6b based on different profiles, such as, child, adult female, adult male, elderly, or the like. Each profile is assigned with a group of second test data that consists of procedural data and expected results. The procedural data include but not limited to, test static electricity based on the test points. Each of the test points is identified by coordinates. The touchpad testing machine 200 includes the positioning controller 7, the ADC 2, a static electricity producer 4, the conductive rubber 5, the display unit 8, a storage unit 9b, and a processing unit 1b. The processing unit 1b includes the positioning control module 11, the comparison module 12, and a static electricity control module 14. Furthermore, like components bear the same reference numerals and will not be described again if they perform the same function or behavior.

The static electricity control module 14 is configured for generating a static electricity control signal and transmitting the static electricity control signal to the static electricity producer 4.

The static electricity producer 4 supplies static electricity to the conductive rubber 5 according to the static electricity control signal, as a consequence, the conductive rubber 5 applies the static electricity on the capacitive touchpad 6b.

The storage unit 9b is configured for storing the second test data associated with the profiles. For exemplary purposes, a plurality of tables including the second test data are illustrated as follows. Each table corresponds to one profile and lists the second test data associated with the profile.

TABLE 5
Adult male Profile

| | Procedural Data/Test static | Expected |
|---|---|---|
| Test Point | electricity | Result |
| A (x1, y1) | S1 | S1a |
| B (x2, y2) | S1 | S1b |
| C (x3, y3) | S1 | S1c |
| D (x4, y4) | S1 | S1d |
| . . . | S1 | . . . |

TABLE 6
Adult female Profile

| | Procedural Data/Test static | Expected |
|---|---|---|
| Test Point | electricity | Result |
| A (x1, y1) | S2 | S2a |
| B (x2, y2) | S2 | S2b |
| C (x3, y3) | S2 | S2c |
| D (x4, y4) | S2 | S2d |
| . . . | S2 | . . . |

TABLE 7
Child Profile

| | Procedural Data/Test static | Expected |
|---|---|---|
| Test Point | electricity | Result |
| A (x1, y1) | S3 | S3a |
| B (x2, y2) | S3 | S3b |
| C (x3, y3) | S3 | S3c |
| D (x4, y4) | S3 | S3d |
| . . . | S3 | . . . |

TABLE 8
Elderly Profile

| | Procedural Data/Test static | Expected |
|---|---|---|
| Test Point | electricity | Result |
| A (x1, y1) | S4 | S4a |
| B (x2, y2) | S4 | S4b |
| C (x3, y3) | S4 | S4c |
| D (x4, y4) | S4 | S4d |
| . . . | S4 | . . . |

When testing the capacitive touchpad 6b with the touch pad testing machine 200 in the second preferred embodiment, the positioning control module 11 reads second test data (i.e., the test points) associated with a corresponding profile (e.g., man) from the storage unit 9b, and controls the movement of the conductive rubber 5 according to the coordinates of the test points so as to touch and test the test points with the conductive rubber 5. When the conductive rubber 5 reaches one of the test points (e.g., point A), the static electricity control module 14 reads the test static electricity (e.g., S1 as that shown in table 5) corresponding to the test point A. When the conductive rubber 5 applies the static electricity on the capacitive touchpad 6b, the capacitive touchpad 6b generates and sends an sensing signal to the ADC 2. The ADC 2 converts the sensing signals into digital values and sends the digital values to the comparison module 12. The comparison module 12 compares the digital values with the expected results (e.g. S1a) from the storage unit 9b, and transmits the comparison result to the displayed unit 8 of the touchpad testing machine 200. The touchpad testing machine 200 repeats this procedure to test other test points.

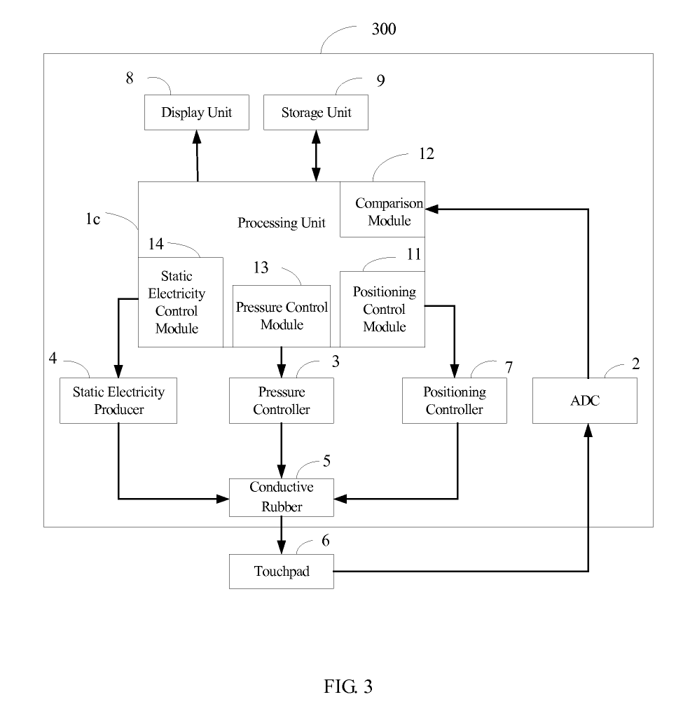

Combination with the first embodiment and the second embodiment, FIG. 3 is a block diagram of the touchpad testing machine 300 in accordance with a third embodiment of the present invention. The touchpad testing machine 300 is configured for testing a touchpad 6 including the resistive touchpad 6a and the capacitive touchpad 6b based on the different profiles, such as, child, adult female, adult male, elderly, or the like. Each profile is assigned with a group of third test data that consists of procedural data and expected results. The procedural data include but not limited to, test pressure, test static electricity based on the test points. Each of the test points is identified by coordinates. The touchpad testing machine 300 includes the positioning controller 7, the ADC 2, the pressure controller 3, the static electricity producer 4, the conductive rubber 5, the display unit 8, a storage unit 9, and a processing unit 1c. The pressing unit 1c includes the position control module 11, the comparison module 12, the pressure control module 13, and the static electricity control module 14.

The storage unit 9 is configured for storing the third test data associated with the profiles. For exemplary purposes, a plurality of tables including the third test data are illustrated as follows. Each table corresponds to one profile and lists the third test data associated with the profile.

TABLE 9
Adult Male Profile

| | Procedural | | | |
|---|---|---|---|---|
| | Data/Test | | Procedural | |
| | Static | Expected Static | Data/Test | Expected |
| Test Point | Electricity | Electricity Result | Pressure | Pressure Result |
| A (x1, y1) | S1 | S1a | P1 | P1a |
| B (x2, y2) | S1 | S1b | P1 | P1b |
| C (x3, y3) | S1 | S1c | P1 | P1c |
| D (x4, y4) | S1 | S1d | P1 | P1d |
| . . . | S1 | . . . | P1 | . . . |

TABLE 10
Adult Female Profile

| | Procedural | | | |
|---|---|---|---|---|
| | Data/Test | | Procedural | Expected |
| | Static | Expected Static | Data/Test | Standard |
| Test Point | Electricity | Electricity Result | Pressure | Pressure Result |
| A (x1, y1) | S2 | S2a | P2 | P2a |
| B (x2, y2) | S2 | S2b | P2 | P2b |
| C (x3, y3) | S2 | S2c | P2 | P2c |
| D (x4, y4) | S2 | S2d | P2 | P2d |
| . . . | S2 | . . . | P2 | . . . |

TABLE 11
Chid Profile

| | Procedural | | | |
|---|---|---|---|---|
| | Data/Test | | Procedural | |
| | Static | Expected Static | Data/Test | Expected |
| Test Point | Electricity | Electricity Result | Pressure | Pressure Result |
| A (x1, y1) | S3 | S3a | P3 | P3a |
| B (x2, y2) | S3 | S3b | P3 | P3b |
| C (x3, y3) | S3 | S3c | P3 | P3c |
| D (x4, y4) | S3 | S3d | P3 | P3d |
| . . . | S3 | . . . | P3 | . . . |

TABLE 12
Elderly Profile

| | Procedural | | | |
|---|---|---|---|---|
| | Data/Test | | Procedural | |
| | Static | Expected Static | Data/Test | Expected |
| Test Point | Electricity | Electricity Result | Pressure | Pressure Result |
| A (x1, y1) | S4 | S4a | P4 | P4a |
| B (x2, y2) | S4 | S4b | P4 | P4b |
| C (x3, y3) | S4 | S4c | P4 | P4c |
| D (x4, y4) | S4 | S4d | P4 | P4d |
| . . . | S4 | . . . | P4 | . . . |

When testing the capacitive touchpad 6a with the touch pad testing machine 300 in the third preferred embodiment, the position control module 11 reads the third test data (i.e., the test points) associated with a corresponding profile (e.g., table 9) from the storage unit 9, and controls a movement of the conductive rubber 5 according to the coordinates of the test points so as to touch and test the test points with the conductive rubber 5. When the conductive rubber 5 reaches one of the test points (e.g., point A), the pressure control module 13 reads the test pressure (e.g., P1 as that shown in table 9) corresponding to the test point A. When the conductive rubber 5 applies the pressing force on the resistive touchpad 6a, the resistive touchpad 6a inducts, and sends an sensing signal to the ADC 2. The ADC 2 converts the sensing signals into digital values and sends the digital values to the comparison module 12. The comparison module 12 compares the digital values with the expected pressure results (e.g. P1 as that shown in table 9) from the storage unit 9, and transmits the comparison result to the displayed unit 8 of the touchpad testing machine 300. The touchpad testing machine 300 repeats this procedure to test other test points.

When testing the capacitive touchpad 6b with the touch pad testing machine 300 in the third preferred embodiment, the position control module 11 reads the third test data (i.e., the test points) associated with a corresponding profile (e.g., table 9) from the storage unit 9, and controls a movement of the conductive rubber 5 according to the coordinates of the test points so as to touch and test the test points with the conductive rubber 5. When the conductive rubber 5 reaches one of the test points (e.g., point A), the static electricity control module 14 reads the test static electricity (e.g., S1 as that shown in table 9) corresponding to the test point A. When the conductive rubber 5 applies the static electricity on the capacitive touchpad 6b, the capacitive touchpad 6b inducts, and sends an sensing signal to the ADC 2. The ADC 2 converts the sensing signals into digital values and sends the digital values to the comparison module 12. The comparison module 12 compares the digital values with the corresponding expected static electricity results (e.g. S1a as that shown in table 9) from the storage unit 9, and transmits a comparison result to the displayed unit 8 of the touchpad testing machine 300. The touchpad testing machine 300 repeats this procedure to test other test points.

Although the present invention has been specifically described on the basis of a preferred embodiment and preferred method thereof, the invention is not to be construed as being limited thereto. Various changes or modifications may be made to the embodiment and method without departing from the scope and spirit of the invention.

What is claimed is:

1. A touchpad testing machine comprising:
a conductive rubber;
a processing unit for generating a pressure control signal and a positioning control signal;
a positioning controller for moving the conductive rubber to touch test points of the touchpad, according to the positioning control signal;
a pressure controller for exerting a pressing force on a touchpad via the conductive rubber, according to the pressure control signal; and
an analog-to-digital converter (ADC) for receiving sensing signals generated from the touchpad through the conductive rubber when receiving the pressing force, and for converting the sensing signals into digital values.

2. The touchpad testing machine according to claim 1, further comprising a storage unit for storing test data associated with profiles, wherein the test data are included in a plurality of tables, and each table corresponding to one profile comprises procedural data and expected results.

3. The touchpad testing machine according to claim 2, wherein the processing unit compares the digital values with expected results, and generates a comparison result.

4. The touchpad testing machine according to claim 3, further comprising a display unit for displaying the comparison result.

5. A touchpad testing machine comprising:
a conductive rubber;
a processing unit for generating a static electricity producing signal and a positioning control signal;
a static electricity producer for accumulating static electricity on a touchpad according to the static electricity producing signal;
a positioning controller for driving the conductive rubber to touch test points of the touchpad, according to the positioning control signal; and
an ADC for receiving sensing signals generated from the touchpad through the conductive rubber after receiving static electricity, and for converting the sensing signals into digital values.

6. The touchpad testing machine according to claim 5 further comprising a storage unit for storing test data associated with profiles, wherein the test data are included in a plurality of tables, and each table corresponding to one profile comprises procedural data and expected results.

7. The touchpad testing machine according to claim 6, wherein the processing unit compares the digital values with standard test values, and generates a comparison result.

8. The touchpad testing machine according to claim 7 further comprising a display unit for displaying the comparison result.
